(19) United States
(12) Patent Application Publication
(10) Pub. No.: US 2025/0328089 A1
(43) Pub. Date: Oct. 23, 2025

(54) RADIATION SOURCE APPARATUS AND METHOD FOR OPERATING THE SAME

(71) Applicant: TAIWAN SEMICONDUCTOR MANUFACTURING COMPANY, LTD., Hsinchu (TW)

(72) Inventors: Shih-Yu TU, Hsinchu County (TW); Chieh HSIEH, Taoyuan City (TW); Han-Lung CHANG, Kaohsiung City (TW); Sheng-Kang YU, Hsinchu City (TW); Li-Jui CHEN, Hsinchu City (TW)

(73) Assignee: TAIWAN SEMICONDUCTOR MANUFACTURING COMPANY, LTD., Hsinchu (TW)

(21) Appl. No.: 18/638,982

(22) Filed: Apr. 18, 2024

(51) Int. Cl. G03F 7/00; B08B 7/00; H05G 2/00

(52) U.S. Cl. CPC G03F 7/70933; B08B 7/0071; G03F 7/70033; G03F 7/70925; H05G 2/003; H05G 2/008; H05G 2/0092

(57) ABSTRACT

A method for operating a radiation source apparatus is provided. The method includes producing extreme ultraviolet (EUV) radiation by emitting a laser onto a target material in a vessel; directing a gas from the vessel into a first debris handling device; blocking the gas from the first debris handling device; and perform a maintenance process on the first debris handling device when the gas is blocked from the first debris handling device.

### BACKGROUND

Photolithography is a process by which a reticle having a pattern is irradiated with light to transfer the pattern onto a photosensitive material overlying a semiconductor substrate. Over the history of the semiconductor industry, smaller integrated chip minimum features sizes have been achieved by reducing the exposure wavelength of optical lithography radiation sources to improve photolithography resolution. Extreme ultraviolet (EUV) lithography, which uses extreme ultraviolet (EUV) light, is a promising next-generation lithography solution for emerging technology nodes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a lithography system according to some embodiments of the present disclosure.

FIG. 2 is schematic view of an EUV radiation source according to some embodiments of the present disclosure.

FIGS. 3A and 3B are schematic view of the EUV radiation source of FIG. 2 at different time durations according to some embodiments of the present disclosure.

FIG. 4A is an exemplary exhaust system of the EUV radiation source of FIG. 2 according to some embodiments of the present disclosure.

FIG. 4B is a diagram showing the time operation sequence of the EUV radiation source including the exhaust system of FIG. 4A according to some embodiments of the present disclosure.

FIG. 5A is an exemplary exhaust system of the EUV radiation source of FIG. 2 according to some embodiments of the present disclosure.

FIG. 5B is a diagram showing the time operation sequence of the EUV radiation source including the exhaust system of FIG. 4A according to some embodiments of the present disclosure.

FIG. 6 is schematic view of an EUV radiation source according to some embodiments of the present disclosure.

FIGS. 7A and 7B are schematic view of the EUV radiation source of FIG. 6 at different time durations according to some embodiments of the present disclosure.

FIG. 8A is an exemplary exhaust system of the EUV radiation source of FIG. 6 according to some embodiments of the present disclosure.

FIG. 8B is a diagram showing the time operation sequence of the EUV radiation source including the exhaust system of FIG. 7A according to some embodiments of the present disclosure.

FIG. 9 show exemplary passive debris isolation device of the exhaust system of the EUV radiation source according to some embodiments of the present disclosure.

FIG. 10 show exemplary passive debris isolation device of the exhaust system of the EUV radiation source according to some embodiments of the present disclosure.

FIG. 11 show exemplary passive debris isolation device of the exhaust system of the EUV radiation source according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An extreme ultraviolet (EUV) photolithography system uses extreme ultraviolet radiation. One method of producing the extreme ultraviolet radiation is to emit a laser to droplets of tin. As the tin droplets are produced into the EUV radiation source vessel, the laser hits the tin droplets and heats the tin droplets to a critical temperature that causes atoms of tin to shed their electrons and become a plasma of ionized tin droplets. The ionized tin droplets emit photons, which is collected by a collector and provided as EUV radiation to an optical lithography system.

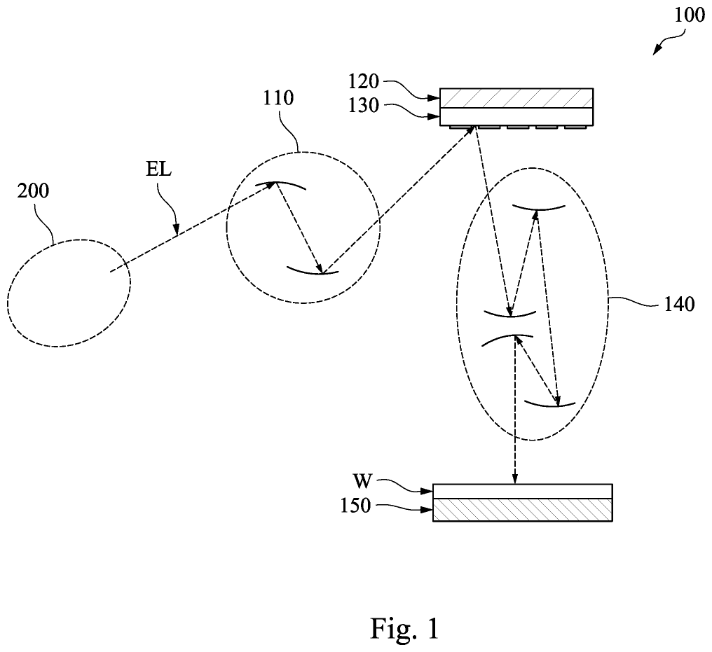

FIG. 1 is a schematic view of a lithography system 100 according to some embodiments of the present disclosure. The lithography system 100 may also be referred to as a scanner that is operable to perform lithography exposing processes with respective radiation source and exposure mode. In some embodiments, the lithography system 100 is an extreme ultraviolet (EUV) lithography system designed to expose a resist layer by EUV light (or EUV radiation). The resist layer is a material sensitive to the EUV light. The EUV lithography system 100 employs a radiation source 200 to generate EUV light EL, such as EUV light having a wavelength ranging between about 1 nm and about 100 nm. In certain examples, the EUV light EL has a wavelength range centered at about 13.5 nm. Accordingly, the radiation source 200 is also referred to as an EUV radiation source 200. The EUV radiation source 200 may utilize a mechanism of laser-produced plasma (LPP) to generate the EUV radiation.

The lithography system 100 also employs an illuminator 110. In some embodiments, the illuminator 110 includes various reflective optics such as a single mirror or a mirror system having multiple mirrors in order to direct the EUV light EL from the radiation source 200 onto a mask stage 120, particularly to a mask 130 secured on the mask stage 120.

The lithography system 100 also includes the mask stage 120 configured to secure the mask 130. In some embodiments, the mask stage 120 includes an electrostatic chuck (e-chuck) used to secure the mask 130. In this context, the terms mask, photomask, and reticle are used interchangeably. In the present embodiments, the lithography system 100 is an EUV lithography system, and the mask 130 is a reflective mask. One exemplary structure of the mask 130 includes a substrate with a low thermal expansion material (LTEM). For example, the LTEM may include TiO₂ doped SiO2, or other suitable materials with low thermal expansion. The mask 130 includes a reflective multi-layer deposited on the substrate. The reflective multi-layer includes plural film pairs, such as molybdenum-silicon (Mo/Si) film pairs (e.g., a layer of molybdenum above or below a layer of silicon in each film pair). Alternatively, the reflective multi-layer may include molybdenum-beryllium (Mo/Be) film pairs, or other suitable materials that are configurable to highly reflect the EUV light EL. The mask 130 may further include a capping layer, such as ruthenium (Ru), disposed on the reflective multi-layer for protection. The mask 130 further includes an absorption layer, such as a tantalum boron nitride (TaBN) layer, deposited over the reflective multi-layer. The absorption layer is patterned to define a layer of an integrated circuit (IC). The mask 130 may have other structures or configurations in various embodiments.

The lithography system 100 also includes a projection optics module (or projection optics box (POB)) 140 for imaging the pattern of the mask 130 onto a semiconductor substrate W secured on a substrate stage (or wafer stage) 150 of the lithography system 100. The POB 140 includes reflective optics in the present embodiments. The light EL that is directed from the mask 130 and carries the image of the pattern defined on the mask 130 is collected by the POB 140. The illuminator 110 and the POB 140 may be collectively referred to as an optical module of the lithography system 100.

In the present embodiments, the semiconductor substrate W is a semiconductor wafer, such as a silicon wafer or other type of wafer to be patterned. The semiconductor substrate W is coated with a resist layer sensitive to the EUV light EL in the present embodiments. Various components including those described above are integrated together and are operable to perform lithography exposing processes.

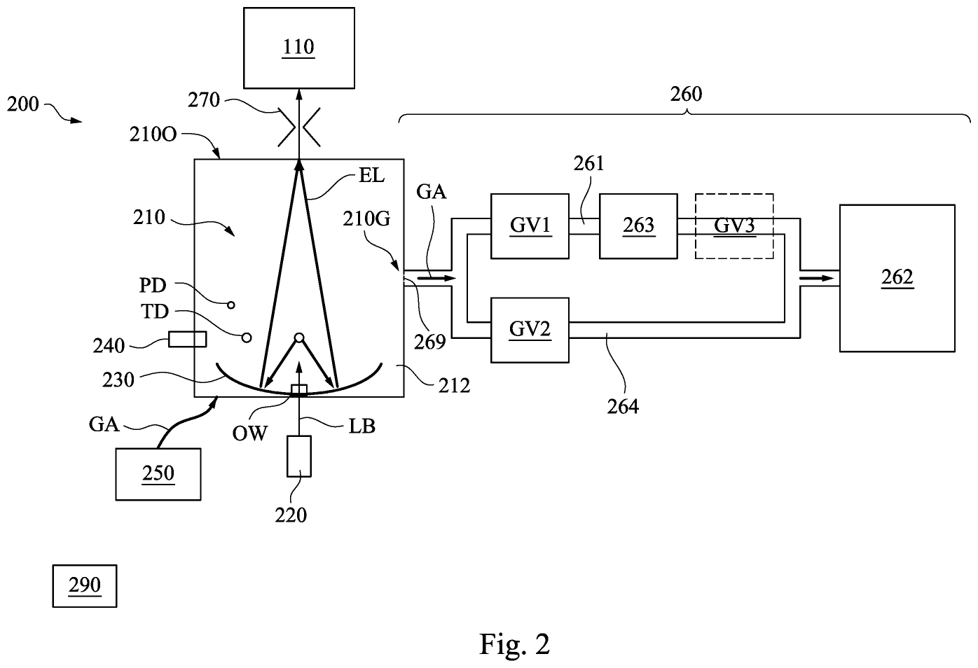

FIG. 2 is schematic view of an EUV radiation source 200 according to some embodiments of the present disclosure. The EUV radiation source 200 may include a vessel 210, a laser source 220, a collector 230, a droplet generator 240, a gas supply module 250, and a gas exhaust system 260. In some embodiments, the vessel 210 has a cover 212 surrounding itself, and the cover 212 is around the collector 230. The radiation source 200 is configured in an enclosed space in the vessel 210. The space in the vessel 210 is maintained in a vacuum environment since the air absorbs the EUV radiation.

The droplet generator 240 is configured to generate droplets of the fuel material TD. The laser source 220 may be at a bottom side of the vessel 210 and below the collector 230 and configured to generate laser beam LB. The laser beam LB is directed to heating the droplets of fuel material TD, such as tin droplets, thereby generating high-temperature plasma (e.g., ionized tin droplets) which further produces the EUV light EL. The collector 230 may collect the EUV light EL, and reflect and focus the EUV light EL to the scanner (i.e., the lithography system 100). In some embodiments, the vessel 210 has a cone shape tapers toward an exit aperture of the vessel 210. In some embodiments, the radiation source 200 may further include an intermediate focus (IF)-cap module 270 out of the exit aperture 210O, and the IF-cap module 270 is configured to provide intermediate focus to the EUV radiation EL from the exit aperture 210O to the scanner (i.e., the lithography system 100).

The laser source 220 may include a carbon dioxide (CO₂) laser source, a neodymium-doped yttrium aluminum garnet (Nd: YAG) laser source, or another suitable laser source to generate a laser beam LB. The laser beam LB is directed through an output window OW integrated with the collector 230. The output window OW adopts a suitable material substantially transparent to the laser beam LB. The laser beam LB is directed to heat the droplets TD, such as tin droplets, thereby generating high-temperature plasma which further produces the EUV light EL. The pulses of the laser source 220 and the droplet generating rate of the droplet generator 240 are controlled to be synchronized such that the droplets TD receive peak powers consistently from the laser pulses of the laser source 220. In some embodiments, the fuel material TD are tin (Sn) droplets. Other materials may also be used for the fuel material TD, for example, a tin-containing liquid material such as eutectic alloy containing tin, lithium (Li), and xenon (Xe).

The collector 230 is designed with suitable coating material and shape, functioning as a mirror for EUV collection, reflection, and focus. In some examples, the collector 230 is designed to have an ellipsoidal geometry. In some examples, the coating material of the collector 230 is similar to the reflective multilayer of the EUV mask 130 (referring to FIG. 1). In some examples, the coating material of the collector 230 includes a ML (such as a plurality of Mo/Si film pairs) and may further include a capping layer (such as Ru) coated on the ML to substantially reflect the EUV light. In some examples, the collector 230 may further include a grating structure designed to effectively scatter the laser beam directed onto the collector 230. For example, a silicon nitride layer may be coated on the collector 230 and patterned to have a grating structure.

In some embodiments, the high-temperature plasma may cool down and become vapors or small particles (collectively, debris) PD. The debris PD may deposit onto the surface of the collector 230, thereby causing contamination thereon. Over time, the reflectivity of the collector 230 degrades due to debris accumulation and other factors such as ion damages, oxidation, and blistering. Once the reflectivity is degraded to a certain degree, the collector 230 reaches the end of its usable lifetime and may need to be swapped out.

In some embodiments, the gas supply module 250 is configured to provide a gas GA into the vessel 210 and particularly into a space proximate the reflective surface of the collector 230. In some embodiments, the gas GA is hydrogen gas, which has less absorption to the EUV radiation. Th gas GA is provided for various protection functions, which includes effectively protecting the collector 230 from the contaminations by tin particles. Other suitable gas may be alternatively or additionally used. The gas GA may be introduced into the collector 230 through openings (or gaps) near the output window OW through one or more gas pipelines. The gas GA may cool Sn particle/debris in the vessel, thereby make high cleanliness in vacuum source chambers.

In some embodiments, the exhaust system 260 may be referred to as an inline debris remover system with an exhaust line 261, a pump 262, and a debris handling system 263. The exhaust line 261 may be connected to a gas outlet 210G of the vessel 210 at the wall of the vessel 210 for receiving the exhaust. To further these embodiments, the exhaust line 261 is connected to the cover 212. The pump 262 draws airflow from the vessel 210 into the exhaust line 261 for effectively pumping out the gas GA. The gas GA may also function to carry some debris PD away from the collector 230 and the cover 212 and into the exhaust system 280. The debris handling system 263 may be coupled with the exhaust line 261, between the vessel 210 and the pump 262, for removing (e.g., scrubbing/filtering) debris PD from the gas GA. In some embodiments, the exhaust system 260 may further include a gas outlet structure 269 disposed at the gas outlet 210G of the vessel near the entrance of the exhaust line 261. The gas outlet structure 269 may be a scrubber, which may passively scrub some debris PD before the gas GA is released out of the vessel 210.

In the present embodiments, the exhaust system 260 may further include a debris isolation device GV1 connected with the exhaust line 261 and coupled between the debris handling system 263 and the vessel 210. In some examples, the exhaust system 260 may optionally include a debris isolation device GV3 connected with the exhaust line 261 and coupled between the debris handling system 263 and the pump 262. In addition, the exhaust system 260 may further include an exhaust line 264 coupled with the entrance of the exhaust line 261 and a debris isolation device GV2 connected with the exhaust line 264 and coupled between the vessel 210 and the pump 262. The pump 262 may also draw airflow from the vessel 210 into the exhaust line 264. The exhaust line 264 is free of the debris handling system 263.

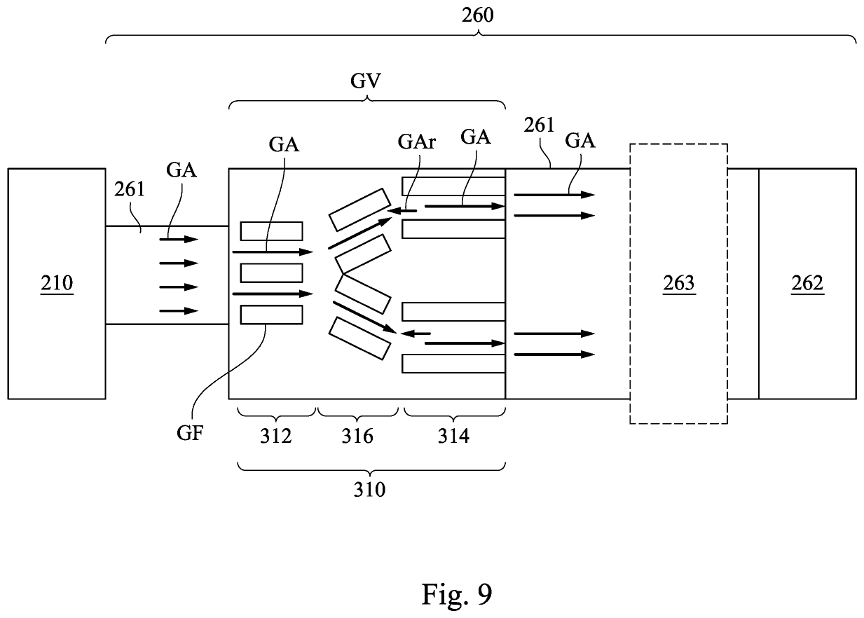

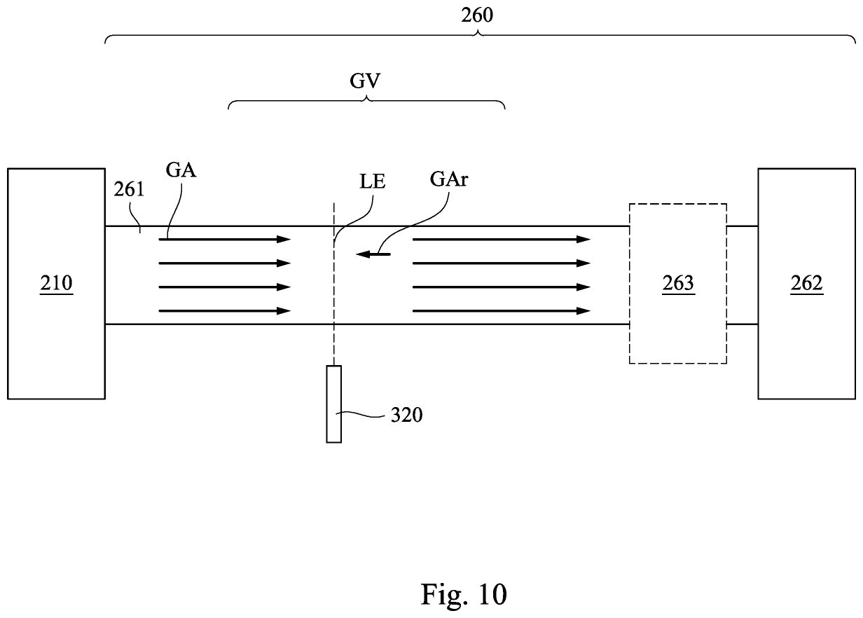

In the present embodiments, one or more of the debris isolation devices GV1-GV3 are active devices, such as gate valves. The EUV radiation source 200 may include a controller 290 electrically connected to the debris isolation devices GV1-GV3 for controlling the flow of the gas GA. In some embodiments, the controller 290 may also be electrically connected to the droplet generator 240 and the laser source 220, thereby controlling the generation of EUV light. The controller 290 may include electronic memory and one or more electronic processors configured to execute programming instructions stored in the electronic memory. In some embodiments, the controller 290 may include processors, central processing units (CPU), multi-processors, distributed processing systems, application specific integrated circuits (ASIC), or the like. In some alternative embodiments, one or more of the debris isolation devices GV1-GV3 may be passive devices stopping debris from flowing back to the vessel 210. For example, the passive debris isolation devices GV1-GV3 may be a light curtain (referring to FIG. 10 later), a gas flow curtain, a liquid curtain, a shielding film curtain (referring to FIG. 9 later), the like, or the combination thereof. In some embodiments, a portion of the debris isolation devices GV1-GV3 are active devices, while another portion of the debris isolation devices GV1-GV3 are passive devices. For example, the debris isolation device GV1 is a gate valve, the debris isolation device GV2 is a passive device, and the debris isolation device GV3 is a gate valve.

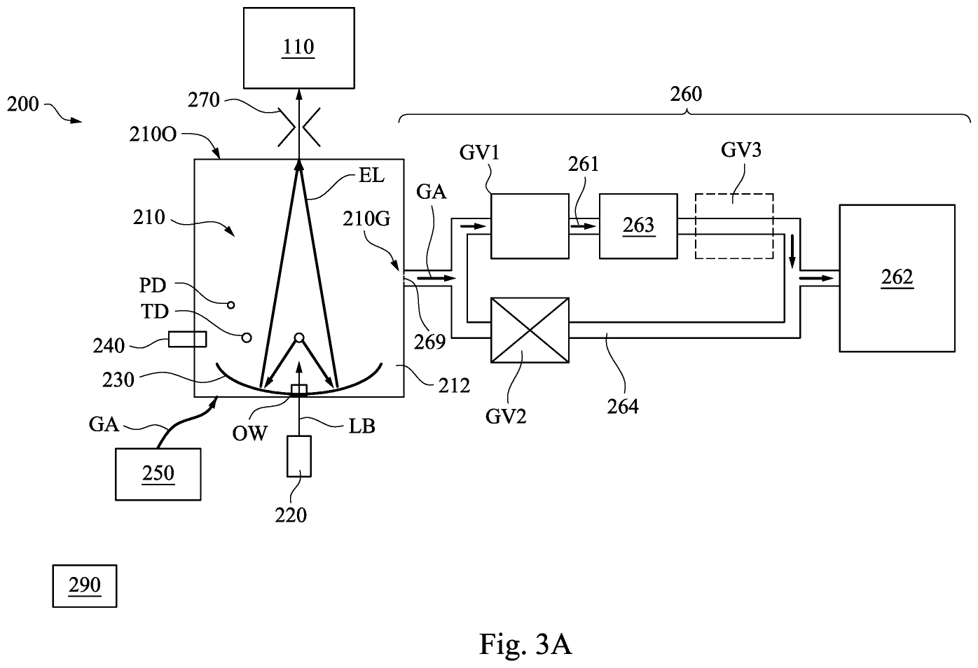

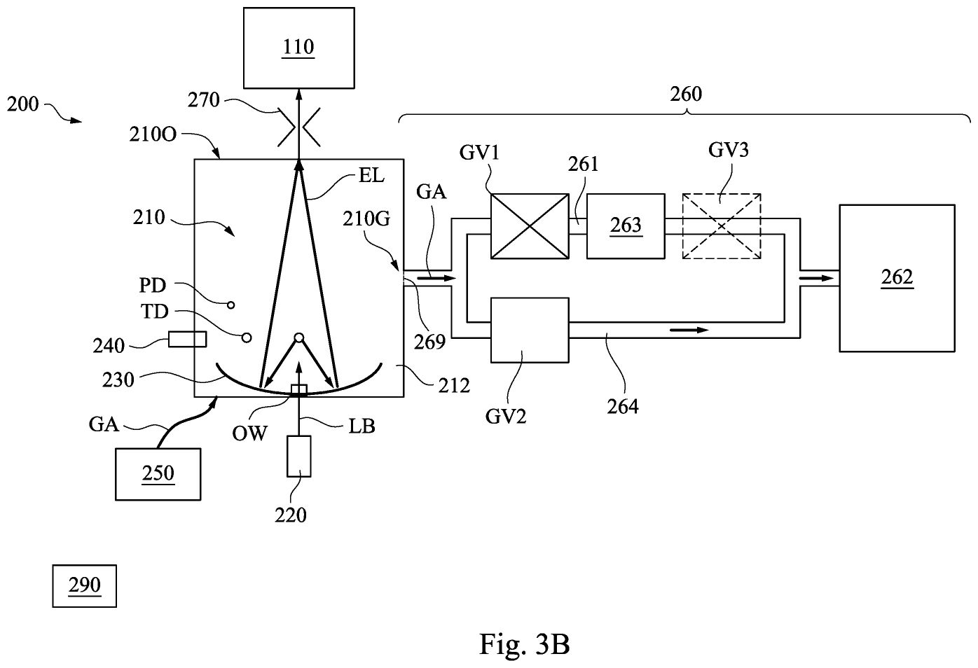

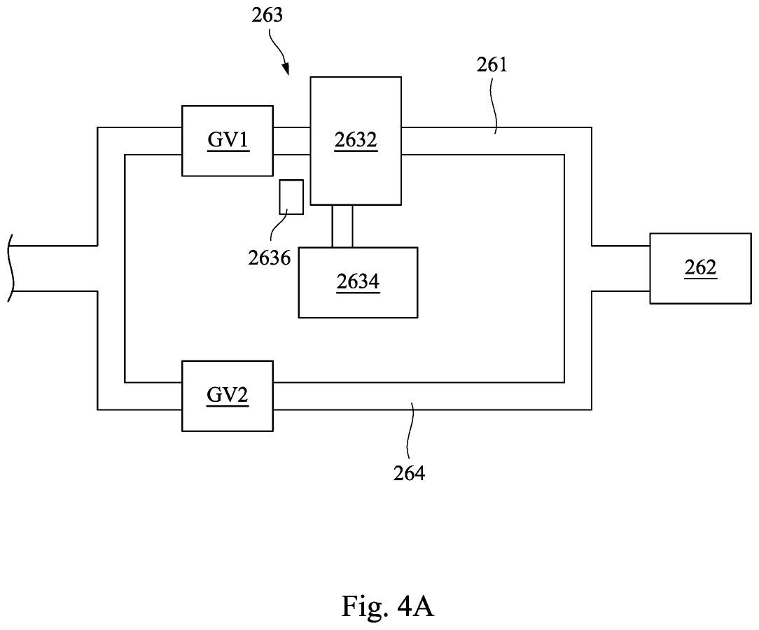

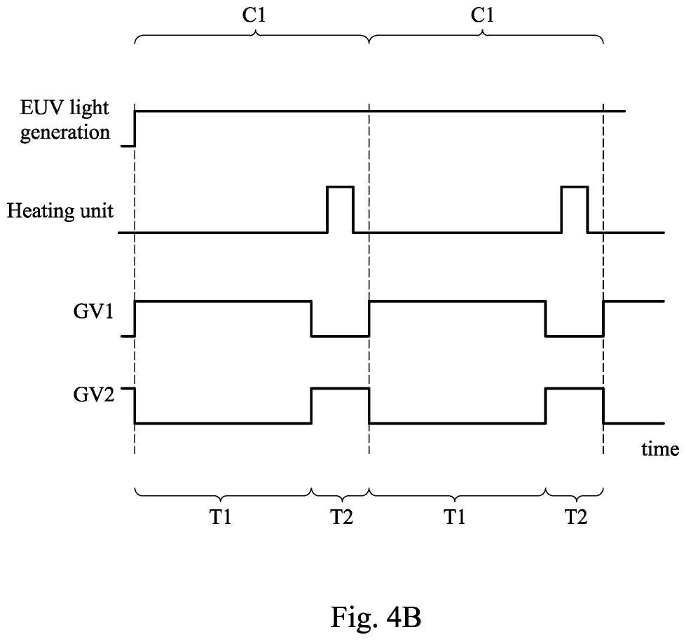

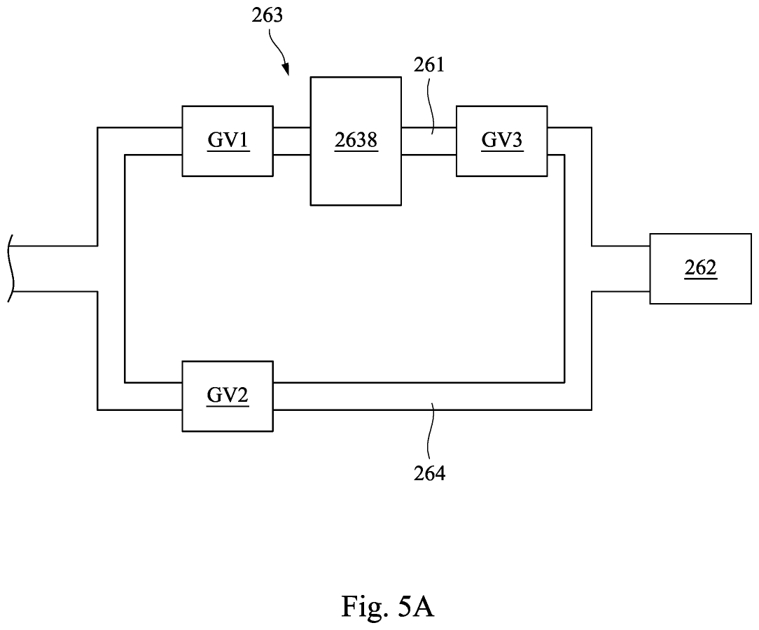

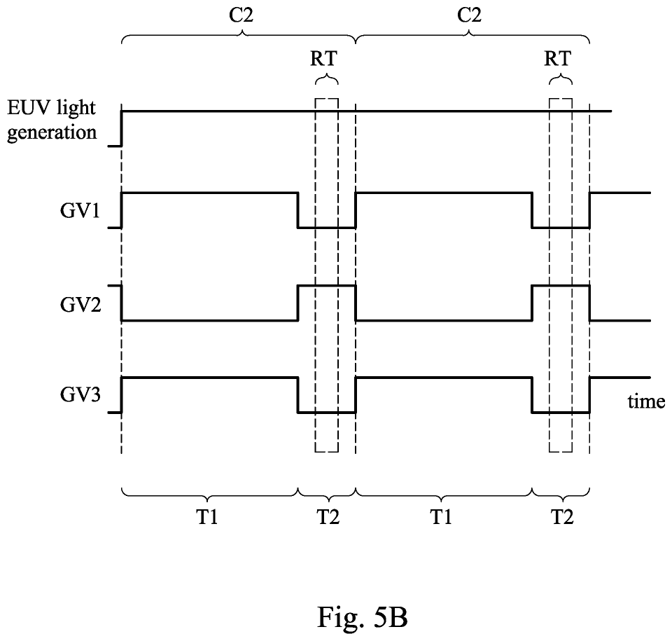

FIGS. 3A and 3B are schematic view of the EUV radiation source of FIG. 2 at different time durations according to some embodiments of the present disclosure. During EUV light EL is generated by the droplet generator 240 and the laser source 220, the active debris isolation devices GV1 and GV2 are controlled, e.g., by the controller 290, such that the gas GA may flow through one of the exhaust lines 261 and 264 and not through another one of the exhaust lines 261 and 264. FIG. 3A may show a first time duration where the gas GA flows to the pump 262 through the exhaust line 261, thereby being scrubbed/filtered by the debris handling system 263. FIG. 3B may show a second time duration where the gas GA flows to the pump 262 through the exhaust line 264, does not pass through the debris handling system 263. During the second time duration as shown in FIG. 3B, a maintenance process may be performed on a debris handling device of the debris handling system 263. For example, depending on the configurations of the debris handling system 263, the maintenance process may include a heating process for melting solidified debris, a replacement process for a new filter, the like, or the combination thereof. Thus, the maintenance process can be performed without stopping the generation of EUV light EL, and thus may be referred to as an in-line maintenance process, which may save operating times of the EUV system. The first time duration (FIG. 3A) and the second time duration (FIG. 3B) may correspond to the time durations T1 and T2 described later in FIGS. 4B and 5B.

FIG. 4A is an exemplary exhaust system 260 of the EUV radiation source of FIG. 2 according to some embodiments of the present disclosure. In the present embodiments, the debris handling system 263 may include a debris handling device 2632 (e.g., scrubber) coupled between the vessel 210 and the pump 262, a box 2634 fluidly connected to the debris handling device 2632 (e.g., scrubber), and a heating unit 2636 adjacent the debris handling device 2632 (e.g., scrubber). The debris handling device 2632 (e.g., scrubber) may passively scrub some debris PD from the gas GA and/or dilute the gas GA after the gas GA is released out of the vessel 210. The debris PD collected by the debris handling device 2632 (e.g., scrubber) may flow to the box 2634, such that the box 2634 can collect liquid debris. The debris collected by the debris handling device 2632 (e.g., scrubber) may solidified, and not easy to flow. In some embodiments, the maintenance process may include providing a temperature higher than the melting point of the debris (e.g., higher than the melting point of tin, which is about at 240 Celsius degrees) by the heating unit 2636, and the heating unit 2636 may be controlled to perform thermal cycle, thereby turning the solidified debris into liquid form.

In some cases, the vessel 210 may be equipped with a heating unit near the cover 212 to provide thermal cycle to clean the vessel. For example, the heating unit may make a temperature near on the inner surface of the cover 212 above a melting point of the debris (e.g., tin), so that the debris does not solidify on the inner surface of the cover 212, and may condense into a liquid form and flow into a storage box at a lower section of the cover 212. However, the heating may cause tin particle spitting such that tin particle may fly from EUV radiation source (or the vessel 210) to the scanner with high speed and cannot be blocked. When operating at temperature larger than the melting point of the debris (e.g., tin), tin spitting phenomena occurs, and microns/nano tin particle will pass through from source to scanner and then cause tin contaminate on a surface of a mask (or reticle) that impact wafer exposure yield.

In some embodiments of the present disclosure, by the disposing the debris handling system 263 away from the vessel 210, the vessel 210 may be operated at a temperature below the melting point of the debris (e.g., tin), and free of the thermal cycle. Through the configuration, the tin spitting phenomena would not occur in the vessel 210, thereby avoiding tin contaminate on the surface of the mask (or reticle). The controller 290 may be electrically connected to the debris isolation device GV1, GV2, the heating unit 2636 for modulating/achieving the thermal cycle of the exhaust system 260.

FIG. 4B is a diagram showing the time operation sequence of the EUV radiation source 200 including the exhaust system 260 of FIG. 4A according to some embodiments of the present disclosure. Reference is made to FIG. 3A, 3B, FIG. 4A, and FIG. 4B. The controller 290 may control the droplet generator 240 and the laser source 220 to generate EUV light. There may be many repeated time cycles C1, each of which includes a first time duration T1 and a second time duration T2 when the EUV light is generated. During the first time duration T1, the active debris isolation device GV1 is turned on (i.e., open), the active debris isolation device GV2 is turned off (i.e., closed), and the heating unit 2636 is turned off. Thus, during the first time duration T1, the gas GA may be drawn/directed from the vessel 210 into the debris handling system 263 (e.g., the debris handling device 2632 (e.g., scrubber)) through the exhaust line 261 by the pump 262, and debris PD in the gas GA may be removed from the gas GA by the debris handling system 263 (e.g., the debris handling device 2632 (e.g., scrubber)). After keeping removing the debris PD from the gas GA for a long time, the debris handling device 2632 (e.g., scrubber) may have a lot of solidified debris thereon, which make the debris difficult to flow to the box 2634. The second time duration T2 follows the first time duration T1. During the second time duration T2, the active debris isolation device GV1 is turned off (i.e., closed), and the active debris isolation device GV2 is turned on (i.e., open), the heating unit 2636 is turned on. Thus, during the second time duration T2, the gas GA may be drawn/directed from the vessel 210 through the exhaust line 264 by the pump 262, being blocked from (e.g., not entering) the exhaust line 261 and the debris handling system 263. Through the operation, a maintenance process is performed. The maintenance process include using the heating unit 2636 to provide thermal energy to the debris handling device 2632 (e.g., scrubber) in the second time duration T2, thereby turning the solidified debris into liquid form, which allow the debris flow from the debris handling device 2632 (e.g., scrubber) to the box 2634. The second time durations T2 may be repeated and referred to as thermal cycles.

In the present embodiments, when the active debris isolation device GV1 is turned off (i.e., closed), debris handling system 263 is in independent chamber isolated from the vessel 210, and the thermal cycle occurs in the independent chamber, thereby spacing tin spitting phenomena from the vessel 210. Stated differently, the exhaust system 260 may operate as a closed system for removing debris PD when the active debris isolation device GV1 is closed.

FIG. 5A is an exemplary exhaust system 260 of the EUV radiation source of FIG. 2 according to some embodiments of the present disclosure. Details of the present embodiments are similar to that of FIG. 4A, except that in the present embodiments, the debris handling system 263 may include a debris handling device 2638 (e.g., filter). The debris handling device 2638 (e.g., filter) may collect debris PD in the gas GA. When the debris handling device 2638 (e.g., filter) is clogged, the debris handling device 2638 (e.g., filter) can be demounted from the debris handling system 263 to be cleaned, and then the cleaned debris handling device 2638 (e.g., filter) may be mounted onto the debris handling system 263. Alternatively, when the debris handling device 2638 (e.g., filter) is clogged, the debris handling device 2638 (e.g., filter) can be replaced with a new filter. For example, the debris handling device 2638 (e.g., filter) is demounted from the debris handling system 263 to be cleaned, and then a new filter may be mounted onto the debris handling system 263.

In the present embodiments, the exhaust system 260 may further include a active debris isolation device GV3 connected with the exhaust line 261 and coupled between the vessel 210 and the pump 262. The active debris isolation devices GV1, GV2, GV3 are cooperated to facilitate the efficiency of the exhaust system 260. For example, the controller 290 (referring to FIG. 2) may be electrically connected to the active debris isolation devices GV1, GV2, GV3 for achieving the replacing or cleaning process of the debris handling device 2638 (e.g., filter).

FIG. 5B is a diagram showing the time operation sequence of the EUV radiation source 200 including the exhaust system 260 of FIG. 5A according to some embodiments of the present disclosure. Reference is made to FIG. 3A, FIG. 3B, FIG. 5A, and FIG. 5B. The controller 290 may control the droplet generator 240 and the laser source 220 to generate EUV light. There may be many repeated time cycles C2, each of which includes a first time duration T1 and a second time duration T2 when the EUV light is generated. During the first time duration T1, the active debris isolation devices GV1 and GV3 are turned on (i.e., open), and the active debris isolation device GV2 is turned off (i.e., closed). Thus, during the first time duration T1, the gas GA may be drawn/directed from the vessel 210 into the debris handling system 263 (e.g., the debris handling device 2638 (e.g., filter)) through the exhaust line 261 by the pump 262, and debris PD in the gas GA may be removed from the gas GA by the debris handling system 263 (e.g., the debris handling device 2638 (e.g., filter)). After keeping removing the debris PD from the gas GA for a long time, the debris handling device 2638 (e.g., filter) may have a lot of debris thereon, which make the gas GA difficult to flow through the debris handling device 2638 (e.g., filter). The second time duration T2 follows the first time duration T1. During the second time duration T2, the active debris isolation devices GV1 and GV3 are turned off (i.e., closed), and the active debris isolation device GV2 is turned on (i.e., open). Thus, during the second time duration T2, the gas GA may be drawn/directed from the vessel 210 through the exhaust line 264 by the pump 262, being blocked from (e.g., not entering) the exhaust line 261 and the debris handling system 263. And, a replacing process RT may be performed to replace the used debris handling device 2638 (e.g., filter) with a new debris handling device 2638 (e.g., filter), thereby allowing the gas GA to flow through the new debris handling device 2638 (e.g., filter).

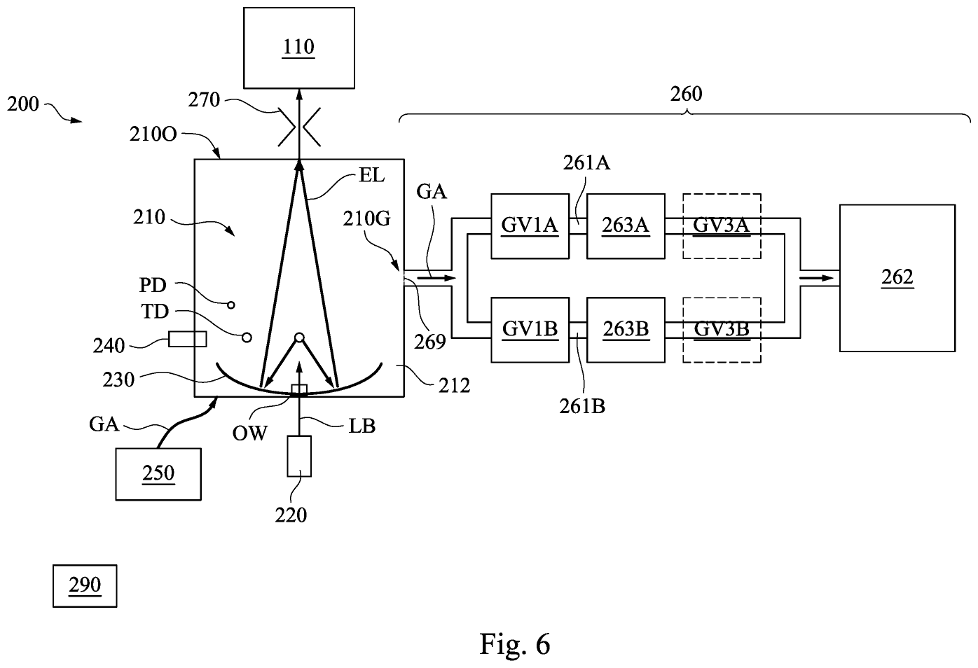

FIG. 6 is schematic view of an EUV radiation source according to some embodiments of the present disclosure. Details of the present embodiments are similar to that of FIG. 2, except that in the present embodiments, the exhaust system 260 may be referred to as an inline debris remover system with two exhaust lines 261A and 261B, a pump 262, and two debris handling systems 263A and 263B. The exhaust lines 261A and 261B are coupled with each other at the entrance thereof. The pump 262 draws airflow from the vessel 210 into the exhaust lines 261A and 262B for effectively pumping out the gas GA. The debris handling systems 263A and 263B may be respectively coupled with the exhaust lines 261A and 261B, between the vessel 210 and the pump 262, for removing debris PD from the gas GA. In the present embodiments, the exhaust system 260 may further include a debris isolation device GV1A and a debris isolation device GV1B. The debris isolation device GV1A is connected with the exhaust line 261A and coupled between the debris handling systems 263A and the vessel 210. The debris isolation device GV1B is connected with the exhaust line 261B and coupled between the debris handling devices 263B and the vessel 210.

In the present embodiments, one or more of the debris isolation devices GVIA, GV1B, GV3A, and GV3B are active devices, such as gate valves. The EUV radiation source 200 may include a controller 290 electrically connected to the debris isolation devices GVIA, GV1B, GV3A, and GV3B for controlling the flow of the gas GA. In some alternative embodiments, one or more of the debris isolation devices GVIA, GV1B, GV3A, and GV3B may be passive devices stopping debris from flowing back to the vessel 210. For example, the passive debris isolation devices GVIA, GV1B, GV3A, and GV3B may be light curtain, gas flow curtain, liquid curtain, shielding film curtain, the like, or the combination thereof. In some embodiments, a portion of the debris isolation devices GV1A, GV1B, GV3A, and GV3B are active devices, while another portion of the debris isolation devices GVIA, GV1B, GV3A, and GV3B are passive devices. For example, the debris isolation device GVIA and GV1B are a gate valve, the debris isolation device GV3A and GV3B are passive devices.

In the present embodiments, the debris handling systems 263A and 263B may include the same or different configurations. In first examples where the debris handling systems 263A and 263B include the different configurations, the debris handling systems 263A may include the debris handling device 2632 (e.g., scrubber), the box 2634, and the heating unit 2636 as illustrated in FIG. 4A, while the debris handling devices 263B may include the debris handling device 2638 (e.g., filter) illustrated in FIG. 5A. In second examples, the debris handling systems 263A and 263B may include the same configurations, such as the debris handling device 2632 (e.g., scrubber), the box 2634, and the heating unit 2636 as illustrated in FIG. 4A. In third examples, the debris handling systems 263A and 263B may include the same configuration, such as the debris handling device 2638 (e.g., filter) illustrated in FIG. 5A. Depending on the configurations of the debris handling systems 263A and 263B, debris isolation devices GV3A and GV3B may be optionally disposed.

Various component and/or elements in the present embodiments are similar to those illustrated in FIG. 2. For example, the configurations of the exhaust lines 261A and 261B may be similar to the exhaust line 261 in FIG. 2; the configurations of the pump 262 may be similar to the exhaust line 261 in FIG. 2; the configurations of the two debris handling systems 263A and 263B may be similar to the debris handling system 263 in FIG. 2; the configurations of the debris isolation devices GV1A and GV1B may be similar to the debris isolation device GV1 in FIG. 2; and the configurations of the debris isolation devices GV3A and GV3B may be similar to the debris isolation device GV3 in FIG. 2. Other details of the present embodiments are similar to those illustrated in FIG. 2., and therefore not repeated herein.

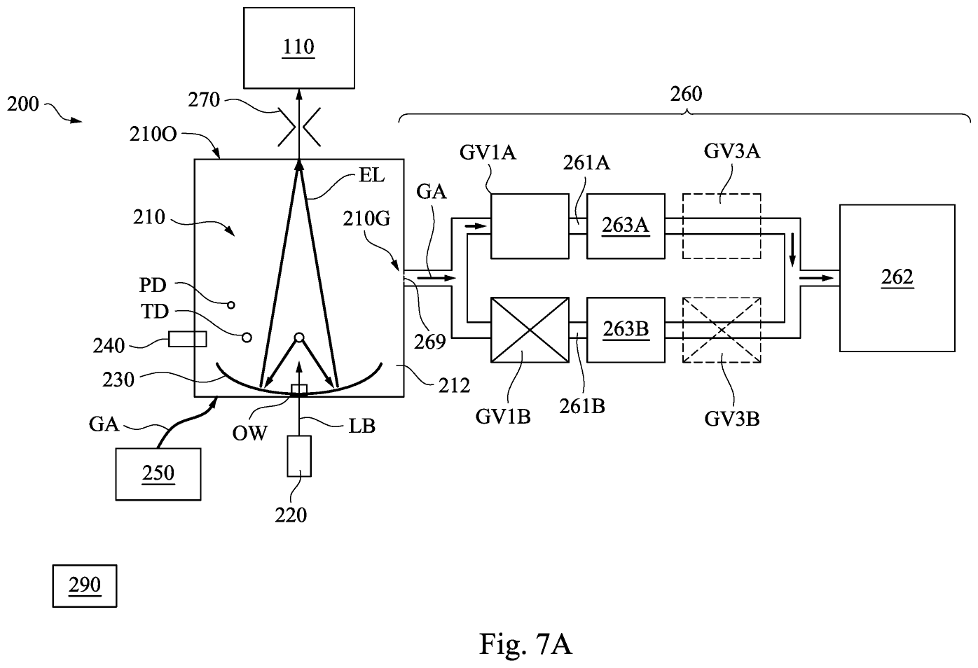

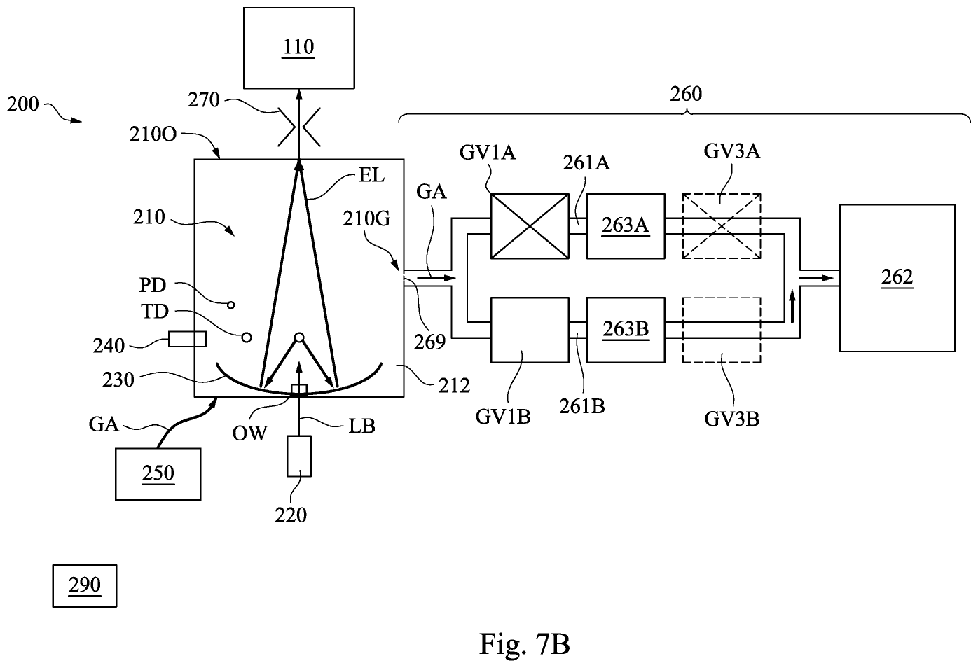

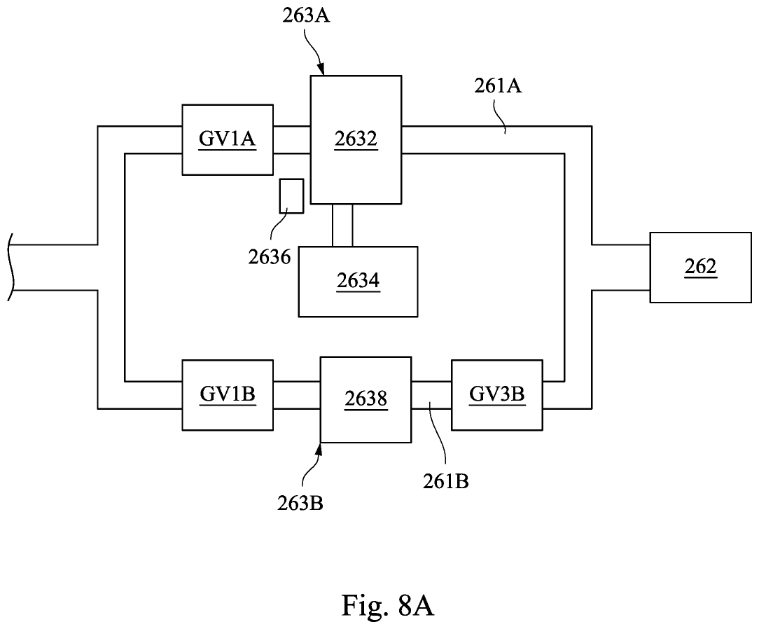

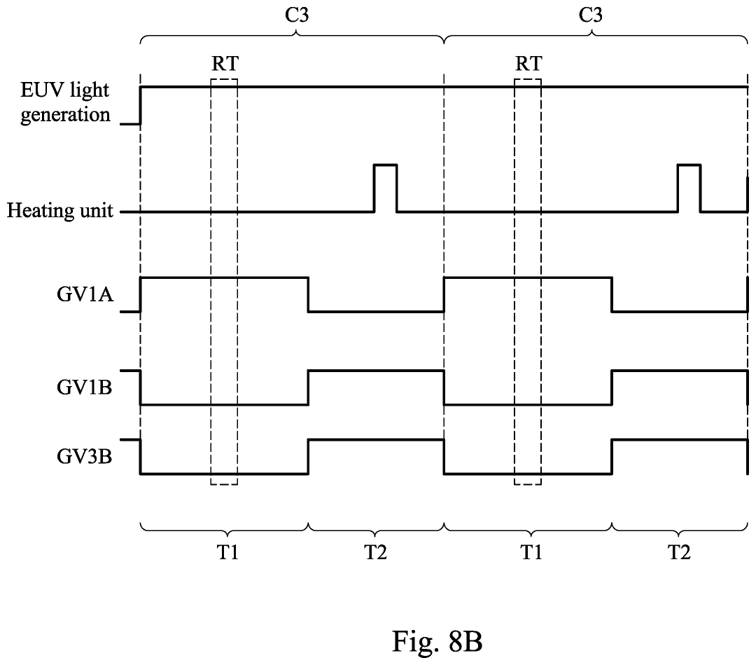

FIGS. 7A and 7B are schematic view of the EUV radiation source of FIG. 6 at different time durations according to some embodiments of the present disclosure. During EUV light EL is generated by the droplet generator 240 and the laser source 220, the debris isolation devices GV1 and GV2 are controlled, e.g., by the controller 290, such that the gas GA may flow through one of the exhaust lines 261A and 261B and not through another one of the exhaust lines 261A and 261B. FIG. 7A may show a first time duration where the gas GA flows to the pump 262 through the exhaust line 261A, thereby being scrubbed/filtered by the debris handling system 263A, and does not pass through the debris handling system 263B. FIG. 3B may show a second time duration where the gas GA flows to the pump 262 through the exhaust line 261B, thereby being scrubbed/filtered by the debris handling system 263B, and does not pass through the debris handling system 263A. During the first time duration as shown in FIG. 7A, a maintenance process may be performed on a debris handling device of the debris handling system 263B. During the second time duration as shown in FIG. 7B, a maintenance process may be performed on a debris handling device of the debris handling system 263A. For example, depending on the configurations of each of the debris handling system 263A/263B, the maintenance process may include a heating process for melting solidified debris, a replacement process for a new filter, the like, or the combination thereof. Thus, the maintenance process can be performed without stopping the generation of EUV light EL, and thus may be referred to as an in-line maintenance process, which may save operating times of the EUV system. The first time duration (FIG. 7A) and the second time duration (FIG. 7B) may correspond to the time durations T1 and T2 described later in FIG. 8B.

FIG. 8A is an exemplary exhaust system 260 of the EUV radiation source 200 of FIG. 6 according to some embodiments of the present disclosure. In the present embodiments, the debris handling system 263A may include the debris handling device 2632 (e.g., scrubber), the box 2634, and the heating unit 2636 as illustrated in FIG. 4A, while the debris handling devices 263B may include the debris handling device 2638 (e.g., filter) illustrated in FIG. 5A.

In the present embodiments, the exhaust system 260 may include a debris isolation device GVIA connected with the exhaust line 261A, and the debris handling systems 263A (e.g., the debris handling device 2632 (e.g., scrubber)) is coupled between the debris isolation device GV1A and the pump 262. In the present embodiments, the exhaust system 260 may include a debris isolation device GV1B and a debris isolation device GV3B connected with the exhaust line 261B, and the debris handling devices 263B (e.g., the debris handling device 2638 (e.g., filter)) is coupled between the debris isolation device GV1B and the debris isolation device GV3B. The debris isolation devices GV1A, GV1B, GV3B are electrically connected to the controller 290 (referring to FIG. 6) and cooperated to facilitate the efficiency of the exhaust system 260.

FIG. 7B is a diagram showing the time operation sequence of the EUV radiation source including the exhaust system 260 of FIG. 7A according to some embodiments of the present disclosure. Reference is made to FIG. 6, FIG. 7A, and FIG. 7B. The controller 290 may control the droplet generator 240 and the laser source 220 (referring to FIG. 6) to generate EUV light. There may be many repeated time cycles C3, each of which includes a first time duration T1 and a second time duration T2 when the EUV light is generated. During the first time duration T1, the debris isolation device GVIA is turned on (i.e., open), the debris isolation device GV1B and GV3B are turned off (i.e., closed), and the heating unit 2636 is turned off. Thus, during the first time duration T1, the gas GA may be drawn/directed from the vessel 210 into the debris handling system 263A (e.g., the debris handling device 2632 (e.g., scrubber)) through the exhaust line 261A by the pump 262, and debris PD in the gas GA may be removed from the gas GA by the debris handling system 263A (e.g., the debris handling device 2632 (e.g., scrubber)). After keeping removing the debris PD from the gas GA for a long time, the debris handling device 2632 (e.g., scrubber) may have a lot of solidified debris thereon, which make the debris difficult to flow to the box 2634. The second time duration T2 follows the first time duration T1. During the second time duration T2, the debris isolation device GV1A is turned off (i.e., closed), and the debris isolation devices GV1B and GV3B are turned on (i.e., open), the heating unit 2636 is turned on. The gas GA may be drawn/directed from the vessel 210 into the debris handling system 263B (e.g., the debris handling device 2638 (e.g., filter)) through the exhaust line 261B by the pump 262, without entering the exhaust line 261A and the debris handling system 263A (e.g., the debris handling device 2632 (e.g., scrubber)). Through the operation, during the second time duration T2, the heating unit 2636 of the debris handling system 263A may provide thermal energy to the debris handling device 2632 (e.g., scrubber), thereby turning the solidified debris into liquid form, which allow the debris flow from the debris handling device 2632 (e.g., scrubber) to the box 2634. In the present embodiments, when the debris isolation device GV1A is turned off (i.e., closed), debris handling system 263A is in independent chamber isolated from the vessel 210, and the thermal cycle occurs in the independent chamber, thereby spacing tin spitting phenomena from the vessel 210.

Also, during the second time duration T2, debris PD in the gas GA may be removed from the gas GA by the debris handling system 263B (e.g., the debris handling device 2638 (e.g., filter)). In dome embodiments, after keeping removing the debris PD from the gas GA for a long time, the debris handling device 2638 (e.g., filter) may have a lot of debris thereon, which make the gas GA difficult to flow through the debris handling device 2638 (e.g., filter). And, during the first time duration T1, a replacing process RT may be optionally performed to replace the used debris handling device 2638 (e.g., filter) with a new debris handling device 2638 (e.g., filter), thereby allowing the gas GA to flow through the new debris handling device 2638 (e.g., filter).

FIG. 9 show exemplary passive debris isolation device GV of the exhaust system 260 of the EUV radiation source according to some embodiments of the present disclosure. As aforementioned, one or more of the debris isolation device GV1-GV3 (referring to FIG. 2) or GV1A, GV1B, GV3A, GV3B (referring to FIG. 6) may be the passive debris isolation device GV. The passive debris isolation device GV is illustrated as a shielding film curtain 310 in the present embodiments. As shown in FIG. 9, the shielding film curtain 310 may include plural shielding elements, such as fins GF. A first group 312 of the fins GF may extend along a direction substantially parallel with a direction of the gas flow GA from the vessel side. A second group 314 of the fins GF may extend along a direction substantially parallel with a direction of the gas flow GA near the pump side. And, a third group 316 of the fins GF is disposed between the first group 312 of the fins GF and the second group 314 of the fins GF. Through the configuration, a gas GAr flowing from the pump side to back to the vessel side (e.g., due to spitting) would hit on the walls of the third group 316 of the fins GF, and debris carried by the gas GAr would be adhered to the walls of the third group 316 of the fins GF. Through the configuration, the shielding film curtain 310 can passively remove debris from the gas GAr, such that debris would not be carried back to the vessel 210. Other details of the present embodiments are similar to those illustrated above, and therefore not repeated herein.

FIG. 10 shows exemplary passive debris isolation device of the exhaust system of the EUV radiation source according to some embodiments of the present disclosure. As aforementioned, one or more of the debris isolation device GV1-GV3 (referring to FIG. 2) or GV1A, GV1B, GV3A, GV3B (referring to FIG. 6) may be the passive debris isolation device GV. The passive debris isolation device GV is illustrated as providing a light curtain in the present embodiments. As shown in FIG. 10, the passive debris isolation device GV may include one or more light source 320 providing light energy LE (e.g., laser) to the gas GA. The light energy LE may hit on the debris, and turn the debris into tiny particles, such that a gas GAr flowing from the pump side to back to the vessel side (e.g., due to spitting) would not carry the debris PD back to the vessel 210. The light energy LE may be referred to as the light curtain between the vessel 210 and the pump side. Other details of the present embodiments are similar to those illustrated above, and therefore not repeated herein.

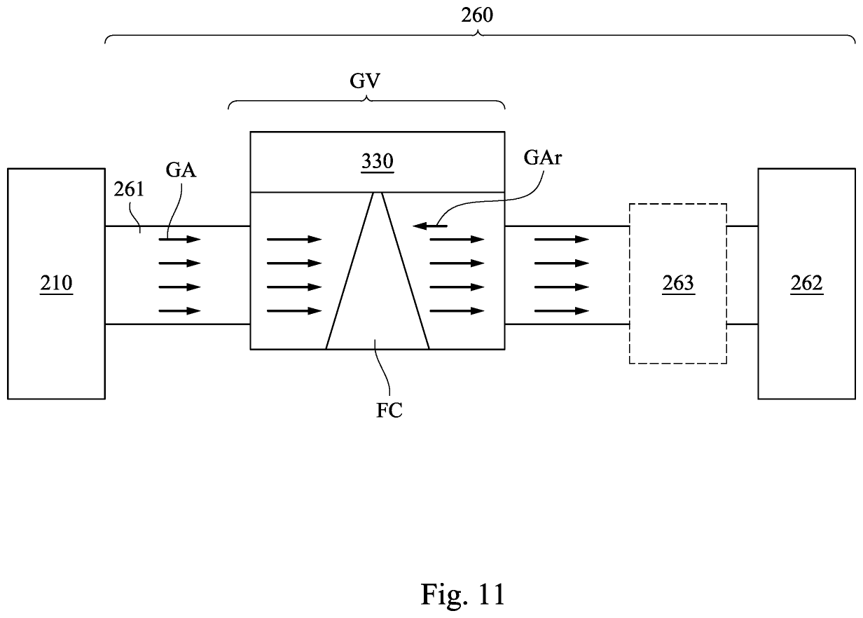

FIG. 11 shows exemplary passive debris isolation device of the exhaust system of the EUV radiation source according to some embodiments of the present disclosure. As aforementioned, one or more of the debris isolation device GV1-GV3 (referring to FIG. 2) or GV1A, GV1B, GV3A, GV3B (referring to FIG. 6) may be the passive debris isolation device GV. The passive debris isolation device GV is illustrated as as providing a liquid curtain or a gas curtain in the present embodiments. As shown in FIG. 11, the passive debris isolation device GV may include one or more liquid/gas source 330 providing a liquid/gas curtain FC to the exhaust line 261. Since the debris is heavier than the liquid/gas, the liquid/gas curtain may stop the propagation of the debris, by the liquid/gas. Through the configuration, a gas GAr flowing from the pump side to back to the vessel side (e.g., due to spitting) would not carry the debris back to the vessel 210. Other details of the present embodiments are similar to those illustrated above, and therefore not repeated herein.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the EUV radiation source is designed with a tin removal system coupled with the vessel by a closed debris isolation device, thereby avoiding tin spitting in EUV radiation source and scanner system. Another advantage is that the prevention maintenance time (e.g., IF Cap clean) can be saved by melting tin in an isolated chamber, thereby reducing the impact on available time. Still another advantage is that by separating the tin removal system from EUV radiation source, spitting is prevented from the EUV vessel, such that the lithography system would become clearer. Still another advantage is that few tin particle residual in EUV radiation source make plasma more stable and support higher power laser excited plasma EUV source to avoiding dirty chamber impact wafer exposure, the laser for plasma can be operated with high repetition rate, and the droplet generator can be operated in high cleanliness chamber with long lifetime operation.

According to some embodiments of the present disclosure, a method for operating a radiation source apparatus is provided. The method includes producing extreme ultraviolet (EUV) radiation by emitting a laser onto a target material in a vessel; directing a gas from the vessel into a first debris handling device; blocking the gas from the first debris handling device; and perform a maintenance process on the first debris handling device when the gas is blocked from the first debris handling device.

According to some embodiments of the present disclosure, a method for operating a radiation source apparatus includes producing EUV radiation by emitting a laser onto a target material in a vessel; moving a gas away from the vessel through a first exhaust line coupling a gas outlet of the vessel to a pump; and removing a debris of the target material in the gas in the first exhaust line.

According to some embodiments of the present disclosure, a radiation source apparatus includes a vessel, a laser source, and an exhaust system. The vessel has an exit aperture. The laser source is disposed at one end of the vessel and configured to emit a laser beam to excite a target material to form a plasma. The exhaust system includes a pump; an exhaust pipe connecting a gas outlet of the vessel to the pump; and a debris handling device coupled with the exhaust pipe and between the gas outlet of the vessel and the pump.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for operating a radiation source apparatus, comprising:
producing extreme ultraviolet (EUV) radiation by emitting a laser onto a target material in a vessel;
directing a gas from the vessel into a first debris handling device;
blocking the gas from the first debris handling device; and
perform a maintenance process on the first debris handling device when the gas is blocked from the first debris handling device.

2. The method of claim 1, wherein blocking the gas from the first debris handling device comprising:
closing a debris isolation device between the first debris handling device and the vessel.

3. The method of claim 1, wherein the maintenance process comprises:
heating the first debris handling device.

4. The method of claim 3, wherein the first debris handling device is a scrubber.

5. The method of claim 3, wherein heating the first debris handling device is performed with a temperature higher than a melting point of the target material.

6. The method of claim 1, wherein the maintenance process comprises:
replacing the first debris handling device with a second debris handling device.

7. The method of claim 6, wherein the first debris handling device is a filter.

8. The method of claim 1, wherein the maintenance process is performed during producing the EUV radiation.

9. The method of claim 1, wherein the first debris handling device is outside the vessel.

10. The method of claim 1, wherein the first debris handling device is fluidly connected to the vessel by an exhaust line.

11. A method for operating a radiation source apparatus, comprising:
producing EUV radiation by emitting a laser onto a target material in a vessel;
moving a gas away from the vessel through a first exhaust line coupling a gas outlet of the vessel to a pump; and
removing a debris of the target material in the gas in the first exhaust line.

12. The method of claim 11, further comprising:
terminating moving the gas away from the vessel through the first exhaust line; and
moving the gas away from the vessel through a second exhaust line coupling the gas outlet of the vessel to the pump when the moving the gas away from the vessel through the first exhaust line is terminated.

13. The method of claim 11, wherein removing the debris of the target material in the gas in the first exhaust line is performed using a debris handling device coupled with the first exhaust line.

14. The method of claim 13, further comprising:
perform a maintenance process on the debris handling device after removing the debris of the target material in the gas in the first exhaust line.

15. The method of claim 11, wherein the removing the debris of the target material in the gas in the first exhaust line is performed during producing the EUV radiation.

16. A radiation source apparatus, comprising:
a vessel having an exit aperture;
a laser source disposed at one end of the vessel and configured to emit a laser beam to excite a target material to form a plasma;
an exhaust system, comprising:
a pump;
an exhaust pipe connecting a gas outlet of the vessel to the pump; and
a debris handling device coupled with the exhaust pipe and between the gas outlet of the vessel and the pump.

17. The radiation source apparatus of claim 16, wherein the debris handling device is a scrubber.

18. The radiation source apparatus of claim 16, wherein the exhaust system further comprising a heating unit adjacent the debris handling device.

19. The radiation source apparatus of claim 16, wherein the debris handling device is a filter.

20. The radiation source apparatus of claim 16, wherein the exhaust system further comprising a debris isolation device coupled with the exhaust pipe and between the gas outlet of the vessel and the debris handling device.
